(19) United States
(12) Patent Application Publication
(10) Pub. No.: US 2004/0158421 A1
(43) Pub. Date: Aug. 12, 2004

(54) Crosstalk checking method

(75) Inventor: Nobufusa Iwanishi, Osaka (JP)

Correspondence Address: McDERMOTT, WILL & EMERY, 600 13th Street, N.W., Washington, DC, 20005-3096, US

(73) Assignee: MATSUSHITA ELECTRIC INDUSTRIAL CO., LTD.

(21) Appl. No.: 10/695,935

(22) Filed: Oct. 30, 2003

(30) Foreign Application Priority Data
Apr. 12, 2002 (JP) P2002-352337

(51) Int. Cl. G01R 13/00

(52) U.S. Cl. 702/69

(57) ABSTRACT

In a parallel line length extracting procedure, a layout and a reference value per pitch describing a restriction value of a parallel line length different according to a line pitch are input, thereby extracting the parallel line length between adjacent lines. In a parallel line length checking procedure per pitch, a line pitch is calculated with respect to the adjacent lines extracted in the parallel line length extracting procedure, the parallel line length between the adjacent lines is compared with the reference value per pitch, and thus, a portion at which crosstalk occurs is determined in the case where the parallel line length is greater.

### BACKGROUND OF THE INVENTION

The present invention relates to a crosstalk checking method for checking crosstalk caused by signal transition of either one of adjacent lines between the adjacent lines in an layout design of a semiconductor integrated circuit configured by connecting basic logical cells or functional macro blocks via inter-cell lines.

The prior art will be described in reference to FIGS. 13 to 17.

Crosstalk is a phenomenon generated between adjacent lines, in which a change in signal in one of the adjacent lines influences a signal on the other adjacent line. One example is illustrated in FIGS. 13A, 13B, 14A and 14B.

A path consisting of a drive cell C51, a line L51 and a driven cell C52 is assumed to be an aggressor which gives an influence of crosstalk; in contrast, a path consisting of a drive cell C53, a line L52 and a driven cell C54 is assumed to be a victim which suffers the influence of the crosstalk.

FIG. 13A illustrates a design technique in the case where no crosstalk is taken into consideration. In this case, a coupling capacity generated between the lines L51 and L52 is represented by a ground capacity such as a capacity Cp1 or a capacity Cp2. An output signal waveform W53 of the drive cell C53 or an input signal waveform W54 of the driven cell C54 is calculated under the condition that the drive cell C53 drives the line L52 having the capacity Cp2. A line delay Dy1 of the line L52 is calculated based on the above-described two signal waveforms. When a design rule ranges from about 0.25 μm to about 0.35 μm, the influence of the crosstalk is small. Therefore, even with the above-described design technique, there have been few differences from an actual operation from the viewpoint of the delay.

However, when the design rule becomes smaller and the interval between the lines becomes very narrow, the situation is varied. FIG. 13B illustrates crosstalk in the case where the interval between the lines L51 and L52 is very narrow. A coupling capacity is represented not as a ground capacity but as a capacity between the lines, like a capacity Cp3, as it is.

As is clear from the comparison between the cases illustrated in FIGS. 13A and 13B, an output signal waveform W53a of the drive cell C53 obtained after delay calculation is different from the output signal waveform W53. In the same manner, an input signal waveform W54a of the driven cell C54 is different from the input signal waveform W54. Similarly, a line delay Dy2 calculated based on the output signal waveform W53a and the input signal waveform W54a is different from the line delay Dy1.

In the case where the transition directions of the output signal waveforms of the drive cells C51 and C53 are the same as each other (for example, in the case where both of the transition directions vary from zero to VDD), the relationships expressed by inequalities (1) to (3) below are established. In contrast, in the case where the transition directions are different from each other, the relationships expressed by inequalities (4) to (6) below are established. Here, the inclination of the signal waveform signifies a signal transition time during which a voltage is varied from zero to VDD or from VDD to zero (that is, it does not signify a rising or falling gradient).

m₅₃>n₅₃ (1)

m₅₄>n₅₄ (2)

Dy1>Dy2 (3)

m₅₃<n₅₃ (4)

m₅₄<n₅₄ (5)

Dy1<Dy2 (6)

wherein m₅₃ designates an inclination of the output signal waveform W53; n₅₃, an inclination of the output signal waveform W53a; m₅₄, an inclination of the input signal waveform W54; and n₅₄, an inclination of the input signal waveform W54a.

The differences obtained by the inequalities (1) to (6) become larger as the coupling capacity Cp3 becomes larger. Furthermore, the differences become larger as the inclination rate η of the signal waveform on the aggressor which gives the influence of the crosstalk becomes greater with respect to the victim which suffers the influence of the crosstalk. Here, the inclination rate η of the signal waveform is expressed by a value calculated based on an equation (7) below.

η=kvic/kagg (7)

wherein kvic represents an inclination of the signal waveform of the victim; in contrast, kagg represents an inclination of the signal waveform of the aggressor.

In other words, the inclination rate η of the signal waveform signifies the inclination of the output signal waveform W53a divided by the inclination of the output signal waveform W53. When the design rule becomes as fine as 0.18 μm or 0.10 μm, the coupling capacity becomes greater. As a result, the difference between the right side and the left side expressed in each of the inequalities (1) to (6) becomes so great that the difference cannot be ignored in view of a timing design.

Moreover, an erroneous operation may be caused by a glitch (a whisker pulse) generated by the crosstalk. FIG. 14A illustrates the state in which an output from a drive cell C51 is varied without any variation in output from a drive cell C53 in the case where a coupling capacity is expressed as a grounding capacity. In this case, there is no coupling capacity between the drive cells C51 and C53, which are, therefore, independent of each other, and thus, no glitch is included in the output from the drive cell C53.

However, in the case illustrated in FIG. 14B in which there is a coupling capacity Cp3, a glitch G1 occurs in the output from the drive cell C53 caused by variations of an output signal waveform W51 of the drive cell C51. When the glitch G1 is large, it is propagated through a line L52 and a driven cell C54, and then, reaches a flip flop FF1 connected to the driven cell C54. If a clock is input into the flip flop FF1 at a timing at which the glitch reaches the flip flop FF1, an error occurs as described below. Namely, although an output signal waveform W55 of the flip flop should be inherently zero, it is output as a signal W55c transited from zero to VDD. Here, the logic is reversed, and thus, an erroneous operation is induced on the following path.

In view of this, techniques capable of coping with the above-described circumstances have been established. One of such techniques is a method for extracting and correcting a portion at which crosstalk is liable to occur, during a layout. In addition, there is a method for verifying the occurrence of crosstalk after a layout is complete.

First of all, a method for extracting a portion at which crosstalk occurs, after a layout is complete will be described with reference to FIG. 15.

In step S81 of a P & R procedure, a layout 30 is produced in consideration of a timing by the use of the coupling capacity between the lines expressed by the ground capacity.

Subsequently, in step S82 of an RC extracting procedure, the layout 30 is input, and then, RC information 31 having a line resistance and a capacity component described therein is extracted. The coupling capacity is described in the RC information 31 as inter-line capacity as it is.

Next, in step S83 of a timing verifying procedure, a delay time of cells and lines constituting the layout 30 is calculated on the basis of the RC information 31. A timing analysis is carried out by the use of the calculated delay information. At the time of the timing analysis, information on a signal transition timing is acquired at each of the input/output terminals of the cells, to be output as timing information 32.

Thereafter, in step S84 of a noise analyzing procedure, first, the signal transition timing is checked on all of the cells on the basis of the timing information 32. Subsequently, adjacent lines, at which the coupling capacity is generated, are drawn out, and then, the drive cell on each of the adjacent lines is extracted. The timing information 32 is checked on the extracted cell, and then, the signal transition timing is checked. That is to say, it is checked as to whether or not timing windows overlap each other between the adjacent lines. If the timing windows overlap each other, correction information 33 is output. All of the cells are evaluated on the above-described timing check and the overlap between the timing windows. Fluctuations in delay caused by the crosstalk are calculated, thereby carrying out static timing verification. As a consequence, it is reported on a path which does not satisfy the timing conditions and the location of a cause which inhibits the satisfaction, thereby finding a portion to be corrected.

Next, a description will be given below of a method for finding a portion at which crosstalk occurs, at the stage of a layout.

In general, a layout tool includes a method for checking a portion at which a timing error occurs caused by the fluctuation in delay caused by the crosstalk in the same manner as described above, and a technique for preventing any crosstalk by restricting a parallel line length between the adjacent lines. In step S91 of a parallel line length extracting procedure illustrated in FIG. 16, in the case where parallel lines having a parallel line length L61 between the adjacent lines, as illustrated in FIG. 17, are included in a layout 40, it is determined whether or not the length of the parallel lines is a reference value 41 or shorter. If the length is greater than the reference value 41, it is determined that the crosstalk occurs on the line, thereby carrying out the layout correction.

As described above, there are several methods for checking the portion, at which the crosstalk occurs. In the method for checking the portion at which the crosstalk occurs, in consideration of the timing after the layout, a substantial work is required in the case where the correction is needed, thereby increasing the number of man-hours. Additionally, after the layout, i.e., after the timing such as a clock is made coincident, and thus, the correction is difficult.

Alternatively, in the method for checking the portion, at which the crosstalk occurs, during the layout a check is made by using a uniform parallel line length, and therefore, the number of portions, at which the crosstalk occurs, is significantly increased. Consequently, a correction time is prolonged or an area is increased to correct the portion at which the crosstalk occurs.

### SUMMARY OF THE INVENTION

In view of the above-described problems observed in the prior art, a principal object of the present invention is to provide a crosstalk checking method, in which the number of processing man-hours can be reduced, an increase in area or electric power consumption can be suppressed, and the incidence rate of deficient products can be reduced.

The other objects, features and advantages according to the present invention will become obvious from a description given below.

In order to solve the above-described problems, with respect to a crosstalk checking method for inspecting crosstalk caused by a signal transition on one of adjacent lines in a semiconductor integrated circuit configured by connecting basic logical cells or functional macro blocks to each other via inter-cell lines, means described below are taken according to the present invention.

As first solving means, a crosstalk checking method according to the present invention is configured so as to include a plurality of procedures described as follows: a parallel line length extracting procedure and a parallel line length checking procedure per pitch. In the parallel line length extracting procedure, a layout and a reference value per pitch are input, so that a parallel line length between adjacent lines is extracted. The reference value per pitch includes restriction values of different parallel line lengths according to line pitches. In the parallel line length checking procedure per pitch, the line pitch is calculated with respect to the adjacent lines extracted in the parallel line length extracting procedure, and then, the parallel line length between the adjacent lines is compared with the reference value per pitch. As a result, it is determined that the crosstalk occurs at a portion on the line if the parallel line length is greater.

With this configuration, since there is provided the restriction value of the parallel line length according to the line pitch between the adjacent lines (i.e., the reference value per pitch), the portion, which has been corrected by using the restriction value of the uniform parallel line length in the prior art, is free from correction. Consequently, it is possible to suppress needless cell insertion or cell sizing, so as to reduce the number of processing man-hours. Furthermore, it is possible to suppress an increase in area or electric power consumption.

As second solving means, a crosstalk checking method according to the present invention is configured so as to include a plurality of procedures described as follows: a parallel line length extracting procedure and a parallel line length checking procedure per drive capability. In the parallel line length extracting procedure, a layout is input, and further, reference values per drive capability including restriction values of different parallel line lengths according to the drive capabilities of cells for driving lines are input, so that the parallel line length between adjacent lines is extracted. Furthermore, in the parallel line length checking procedure per drive capability, the reference value per drive capability corresponding to the drive capability of the cell for driving the line is extracted with respect to the adjacent lines extracted in the parallel line length extracting procedure, and then, it is compared with the parallel line length between the adjacent lines, and thus, the line is determined to be a portion at which the crosstalk occurs if the parallel line length is greater.

The function with the above-described configuration will be as follows: the crosstalk is a phenomenon, in which a timing is varied or a voltage is fluctuated due to the aid of electric charging or the inhibition of the electric charging by electric discharging on one of the lines during the electric charging on the other line with respect to a coupling capacity between the adjacent lines. Consequently, the cell having the stronger drive capability is less influenced by the electric charging or discharging to the coupling capacity from the other than the cell having the weaker drive capability, thereby reducing the influence of the crosstalk. Therefore, the restriction value of the parallel line length can be varied according to the magnitude of the drive capability. With this configuration, since there is provided the restriction value of the parallel line length according to the drive capability of the cell for driving the line (i.e., the reference value per drive capability), the portion, which has been corrected by using the restriction value of the uniform parallel line length in the prior art, is free from correction. Consequently, it is possible to suppress needless cell insertion or cell sizing, so as to reduce the number of processing man-hours. Furthermore, it is possible to suppress an increase in area or electric power consumption.

As third solving means, a crosstalk checking method according to the present invention is configured so as to include a plurality of procedures described as follows: a parallel line length extracting procedure, a clock net extracting procedure and an aggressor/victim determining procedure. In the parallel line length extracting procedure, a layout is input, and further, a reference value including a restriction value of a parallel line length is input, so that the parallel line length between adjacent lines is extracted. Moreover, in the clock net extracting procedure, a path is traced by using a net list and a point of a clock source as inputs, and then, a clock net is extracted. Additionally, in the aggressor/victim determining procedure, with respect to the extracted net, the adjacent lines are classified into a line which suffers an influence of crosstalk and a line which gives an influence of crosstalk based on the magnitude of the inclination of the signal waveform at a cell output terminal by using, as an input, inclination information including an inclination of a signal waveform at a cell output terminal in the net list, and thus, it is determined that the net is on the side which suffers the influence of the crosstalk. Here, the line, on which the influence of the crosstalk is given, out of the adjacent lines is referred to as “an aggressor”; in contrast, the line which suffers the influence of the crosstalk so as to generate delay fluctuations or a glitch is referred to as “a victim”.

With this configuration, attention paid to the clock net verifies as to whether or not the crosstalk occurs in the clock net. When the clock net is delayed or fluctuated by the crosstalk, a skew included in the entire LSI is collapsed, thereby raising a fear of an erroneous operation. When a glitch occurs, a clock is generated at an unexpected timing, thereby inducing a logical error so as to induce an erroneous operation. That is to say, such a design as to make the clock a victim need be corrected. Since the clock net includes the skew, the clock net is not corrected but the net adjacent thereto is corrected. Consequently, it is possible to suppress occurrence of deficiency on the market, so as to enhance a yield.

As fourth solving means, a crosstalk checking method according to the present invention is configured so as to include a plurality of procedures described as follows: a parallel line length extracting procedure, a delay fluctuation calculating procedure and a delay information outputting procedure. In the parallel line length extracting procedure, a layout is input, and further, a reference value including a restriction value of a parallel line length is input, so that the parallel line length between adjacent lines are extracted. Moreover, in the delay fluctuation calculating procedure, the parallel line length is input, and further, a table of delay fluctuations is input, so that a calculation is carried out as to how much delay fluctuation the parallel line length extracted in the parallel line length extracting procedure corresponds to. The table of the delay fluctuations describes the delay fluctuations fluctuated in the case of the occurrence of the crosstalk according to the drive capability of the cell for driving the parallel line. Additionally, in the delay information outputting procedure, the delay fluctuation calculated in the delay fluctuation calculating procedure is output as the delay information for verifying a timing.

With this configuration, the delay fluctuation fluctuated by the crosstalk is calculated based on the parallel line length, and then, the timing is verified based on the calculated delay fluctuation, thereby finding a portion at which the crosstalk occurs. Even if the parallel line length between adjacent lines is great, it is unnecessary to correct the great parallel line length at a portion with a sufficient timing, thus reducing the number of man-hours required for correction.

As fifth solving means, a crosstalk checking method according to the present invention is configured so as to include a plurality of procedures described as follows: a parallel line length extracting procedure, a drive capability determining procedure and a parallel line length checking procedure per drive capability. In the parallel line length extracting procedure, a layout is input, and further, a reference value including a restriction value of a parallel line length is input, so that the parallel line length between adjacent lines is extracted. Moreover, in the drive capability determining procedure, a library including delay information is input, and further, a standard master cell having a plurality of drive capabilities is input, thereby calculating a determining value of the drive capability per drive capability of the master cell based on information on an inclination of a waveform of an output signal in the library with respect to a target cell block having an unknown drive capability such as an IP block, and subsequently, the determining value of the drive capability of the target cell block is calculated, so as to determine the drive capability of the target cell block by comparison. Here, the master cell signifies a cell which is registered as a standard cell such as an inverter or a buffer and for which a plurality of drive capabilities are prepared. In the parallel line length checking procedure per drive capability, the crosstalk is determined based on the restriction value of the parallel line length corresponding to the drive capability determined in the drive capability determining procedure with respect to the adjacent lines extracted in the parallel line length extracting procedure in the case where the adjacent lines are driven by the target cell block.

The function with the above-described configuration will be as follows: in the case where the IP block or the cell is introduced from the outside of a company, it is usual that the concept of the drive capability is different from that of its own company, and further, the drive capability of the introduced IP block or cell is unclear in many cases. As to the target cell block having the unknown drive capability, the drive capability is determined, and then, a portion at which the crosstalk occurs is checked. Consequently, the portion to be actually corrected is identified, and thus, the layout can be corrected while suppressing an increase in unnecessary area.

As sixth solving means, a crosstalk checking method according to the present invention is configured so as to include a plurality of procedures described as follows: a parallel line length extracting procedure, a boundary information extracting procedure, a hierarchy architecting procedure and a parallel line length checking procedure. In the parallel line length extracting procedure, a hierarchy designed layout is input, and further, a reference value including a restriction value of a parallel line length is input, so that the parallel line length between adjacent lines is extracted per hierarchy. Moreover, in the boundary information extracting procedure, a connection relationship between the lines across a hierarchy is checked based on a net list of each of the hierarchies. Additionally, in the hierarchy architecting procedure, the parallel line length across the hierarchy is calculated by summing up the parallel line lengths extracted in the hierarchies with respect to the same net of the adjacent lines across the hierarchy. In addition, in the parallel line length checking procedure, the parallel line length across the hierarchy is compared with a predetermined reference value, thereby determining a portion at which the crosstalk occurs.

With this configuration, even with the hierarchy design, the parallel line length is checked in a hierarchy developed state, thus alleviating the adverse influence of the crosstalk.

The foregoing and other aspects will become apparent from the following description of the invention when considered in conjunction with the accompanying drawing figures.

### BRIEF DESCRIPTION OF THE DRAWING FIGURES

FIG. 1 is a flowchart illustrating the technique for varying a restriction value of a parallel line length as a determination comparing reference according to a line pitch in determining a portion at which rosstalk occurs in a layout in a crosstalk checking method in a first embodiment according to the present invention;

FIGS. 2A and 2B are diagrams illustrating specific examples of FIG. 1;

FIG. 3 is a flowchart illustrating the technique for varying a parallel line length for restriction according to drive capability of a line driving cell in determining a portion at which crosstalk occurs in a layout in a crosstalk checking method in a second embodiment according to the present invention;

FIGS. 4A and 4B are diagrams illustrating specific examples of FIG. 3;

FIG. 5 is a flowchart illustrating the technique for checking a parallel line length while paying attention to a clock line in determining a portion at which crosstalk occurs in a layout in a crosstalk checking method in a third embodiment according to the present invention;

FIGS. 6A and 6B are diagrams illustrating specific examples of FIG. 5;

FIG. 7 is a flowchart illustrating a method for calculating a delay fluctuation based on a parallel line length between adjacent lines, so as to verify a timing in determining a portion at which crosstalk occurs in a layout in a crosstalk checking method in a fourth embodiment according to the present invention;

FIG. 8A is a diagram illustrating a specific example of FIG. 7;

FIG. 8B is a table of delay fluctuations;

FIG. 9 is a flowchart illustrating a method for determining drive capability with respect to a block/cell having an unknown drive capability such as an IP, so as to restrict a parallel line length in determining a portion at which crosstalk occurs in a layout in a crosstalk checking method in a fifth embodiment according to the present invention;

FIG. 10 is a flowchart illustrating a detailed subdividing procedure of the drive capability determining procedure illustrated in FIG. 9;

FIG. 11 is a flowchart illustrating a method for checking a parallel line length between adjacent lines adjacent to each other across a hierarchy with respect to a hierarchy design in determining a portion at which crosstalk occurs in a layout in a crosstalk checking method in a sixth embodiment according to the present invention;

FIGS. 12A and 12B are diagrams illustrating specific examples of the parallel line length checking method illustrated in FIG. 11;

FIGS. 13A and 13B are diagrams illustrating a phenomenon of crosstalk;

FIGS. 14A and 14B are other diagrams illustrating the phenomenon of the crosstalk;

FIG. 15 is a conventional design flowchart in consideration of crosstalk;

FIG. 16 is a flowchart illustrating a conventional crosstalk coping method at the time of a layout; and

FIG. 17 is a diagram illustrating a specific example of FIG. 16.

In all these figures, like components are indicated by the same numerals.

### DETAILED DESCRIPTION

A crosstalk checking method in the preferred embodiments according to the present invention will be described below in reference to the accompanying drawings.

### First Embodiment

A description will be given below of a crosstalk checking method in a first embodiment according to the present invention.

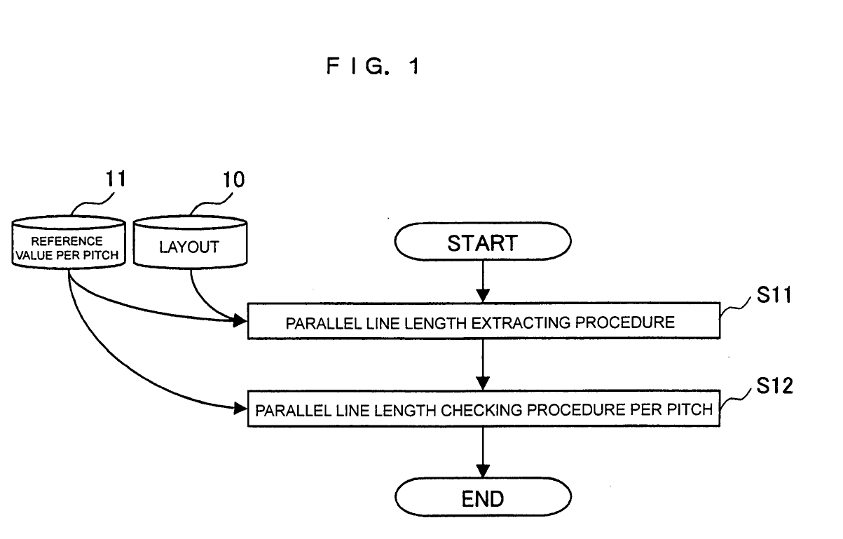

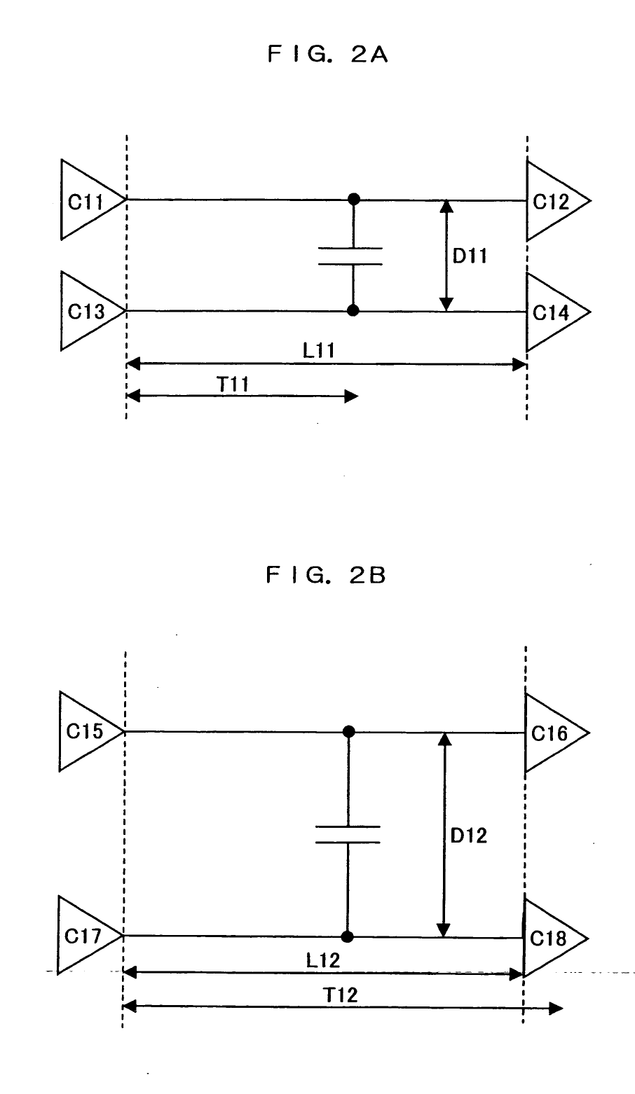

FIG. 1 is a flowchart illustrating the technique for varying a restriction value of a parallel line length as a determination comparing reference according to a line pitch in determining a portion at which crosstalk occurs in a layout; and FIGS. 2A and 2B are diagrams illustrating specific examples of FIG. 1.

In FIG. 1, step S11 designates a parallel line length extracting procedure; step S12 denotes a parallel line length checking procedure per pitch; reference numeral 11 designates a reference value per pitch; and reference numeral 10 denotes a layout.

In FIGS. 2A and 2B, reference characters C11 to C18 designate cells; L11 and L12, parallel line lengths between adjacent lines; T11 and T12, restriction values of the parallel line lengths per pitch, which are described in the reference value 11 per pitch; and D11 and D12, line pitches, each of which indicates a distance between the line centers of the adjacent lines.

In step S11 of the parallel line length extracting procedure, the parallel line length between the adjacent lines is extracted based on the layout 10 and the reference value 11 per pitch. At this time, the restriction value of the parallel line length to be referred to is a minimum value out of the parallel line lengths per pitch described in the reference value 11 per pitch.

Explanation will be provided on the reference value 11 per pitch. The restriction values of the different parallel line lengths per line pitch are described in the reference value 11 per pitch. The restriction value of the parallel line length per line pitch has been previously obtained by using a circuit simulator such as “hspice”.

A description will be given of the relationship between the line pitch and the restriction value of the parallel line length. As illustrated in FIGS. 2A and 2B, the relationship between the line pitch D11 and the line pitch D12 satisfies the following inequality (8):

D11<D12 (8)

In this case, the relationship between the restriction value T11 of the parallel line length and the restriction value T12 of the parallel line length satisfies the following inequality (9):

T11<T12 (9)

As the line pitch becomes greater, a coupling capacity between the adjacent lines becomes smaller. As a result, an influence of crosstalk becomes smaller. Consequently, since the influence of the crosstalk becomes smaller with the greater line pitch, the restriction value of the parallel line length becomes greater.

Subsequently, in step S12 of the parallel line length checking procedure per pitch, the parallel line length is checked based on the restriction value of the parallel line length corresponding to the line pitch. In the examples illustrated in FIGS. 2A and 2B, as a result of the comparison of the restriction value T11 of the parallel line length corresponding to the line pitch D11 with the parallel line length L11, it is found that the parallel line length L11 is greater, and therefore, it is determined that the pair of adjacent lines are a portion at which crosstalk occurs. Next, as a result of the comparison of the restriction value T12 of the parallel line length corresponding to the line pitch D12 with the parallel line length L12, it is found that the parallel line length L12 is shorter, and therefore, it is determined that the pair of adjacent lines are not a portion at which crosstalk occurs. Hereinafter, the same processing is performed with respect to all of the adjacent lines, so that it is determined whether or not the line is a portion at which crosstalk occurs. At the portion at which crosstalk occurs, the layout is corrected. At the portion at which no crosstalk occurs, the layout is not corrected.

As described above, the restriction value of the parallel line length corresponding to the line pitch between the adjacent lines is provided such that the number of layout correcting portions can be more reduced in comparison with the prior art in which the processing is performed based on the uniform restriction value of the parallel line length. As a consequence, it is possible to reduce the number of processing man-hours, and further, to suppress an increase in area. Moreover, needless cell insertion or cell sizing can be prevented by determining not to correct a portion which has been corrected in the prior art, thus producing the effect of suppression of an increase in electric power consumption.

### Second Embodiment

A description will be given below of a crosstalk checking method in a second embodiment according to the present invention.

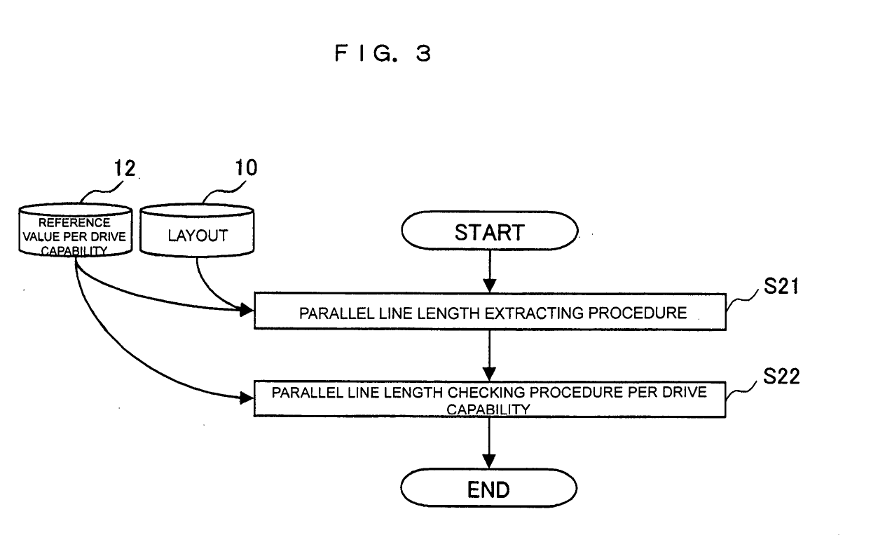

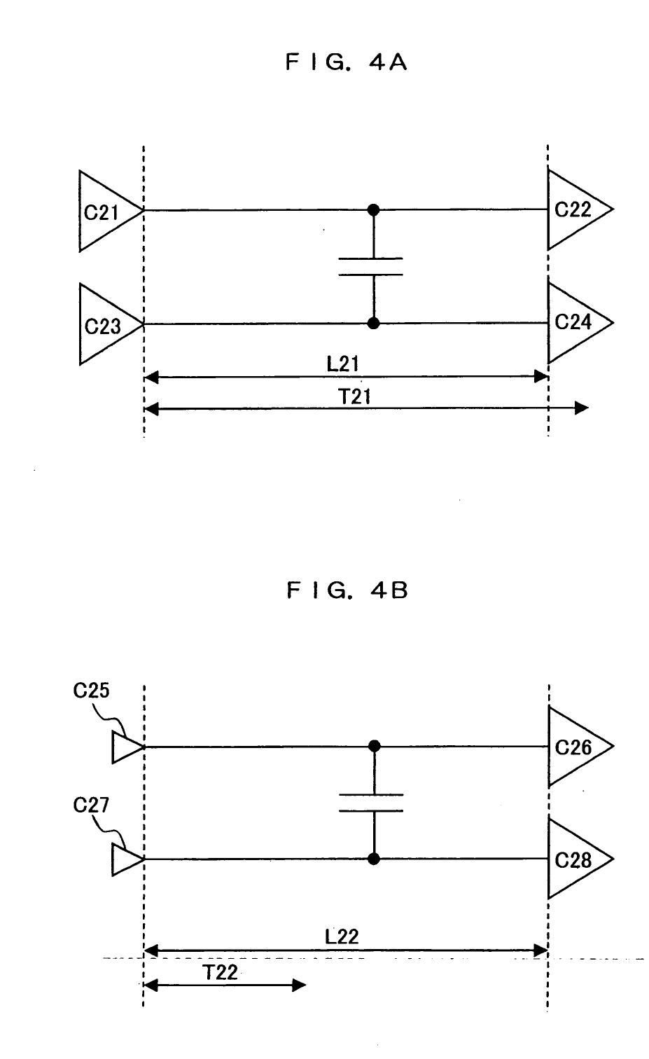

FIG. 3 is a flowchart illustrating the technique for varying a parallel line length for restriction according to drive capability of a line driving cell in determining a portion at which crosstalk occurs in a layout; and FIGS. 4A and 4B are diagrams illustrating specific examples of FIG. 3.

In FIG. 3, step S21 designates a parallel line length extracting procedure; step S22 denotes a parallel line length checking procedure per drive capability; and reference numeral 12 denotes a reference value per drive capability. In FIGS. 4A and 4B, reference characters C21 to C28 designate cells; L21, a parallel line length as a length at a portion at which adjacent lines to be driven by the cells C21 and C23 are parallel to each other; L22, a parallel line length between adjacent lines to be driven by the cells C25 and C27; and T21 and T22, restriction values of the parallel line length per drive capability, which are described in the reference value 12 per drive capability.

In step S21 of the parallel line length extracting procedure, the parallel line length between the adjacent lines is extracted based on a layout 10 and the reference value 12 per drive capability. At this time, the restriction value of the parallel line length for use in extracting is a minimum value described in the reference value 12 per drive capability.

Explanation will be provided on the reference value 12 per drive capability. The restriction value of the parallel line length to be checked per drive capability of the line driving cell is described in the reference value 12 per drive capability. The restriction value of the parallel line length per drive capability has been previously obtained by using a circuit simulator such as “hspice”. A description will be given of the relationship between the drive capability and the restriction value of the parallel line length. The relationship between the drive capability of the cell C21 and the drive capability of the cell C25 satisfies the following inequality (10):

drive capability of cell C21>drive capability of cell C22 (10)

In this case, the relationship between the restriction value T21 of the parallel line length and the restriction value T22 of the parallel line length satisfies the following inequality (11):

T21>T22 (11)

As the drive capability becomes stronger, electric charging force and electric discharging force to a coupling capacity between the adjacent lines become stronger. Crosstalk is a phenomenon in which a timing is varied or a voltage is fluctuated due to the aid of electric charging or the inhibition of the electric charging by electric discharging on one of the lines during the electric charging on other line with respect to the coupling capacity between the adjacent lines. Therefore, the coupling capacity is not relatively susceptible to the influence of the electric charging or the electric discharging from the other with the stronger drive capability than with the smaller drive capability, thereby reducing the influence of the crosstalk. As a result, it is possible to vary the restriction value of the parallel line length according to the magnitude of the drive capability.

Subsequently, in step S22 of the parallel line length checking procedure per drive capability, the parallel line length is checked based on the restriction value of the parallel line length corresponding to the drive capability of the line driving cell. In the examples illustrated in FIGS. 4A and 4B, as a result of the comparison of the restriction value T21 of the parallel line length corresponding to the drive capability of the cell C21 with the parallel line length L21, it is found that the parallel line length L21 is shorter, and therefore, it is determined that the pair of adjacent lines are not a portion at which crosstalk occurs. Next, as a result of the comparison of the restriction value T22 of the parallel line length corresponding to the drive capability of the cell C25 with the parallel line length L22, it is found that the parallel line length L22 is longer, and therefore, it is determined that the pair of adjacent lines are a portion at which crosstalk occurs. Hereinafter, the same processing is performed with respect to all of the adjacent lines, so that it is determined whether or not the line is a portion at which crosstalk occurs. At the portion at which crosstalk occurs, a layout is corrected. On the adjacent lines which are determined as the portion at which no crosstalk occurs, no layout is corrected.

As described above, the restriction value of the parallel line length corresponding to the drive capability of the line driving cell is provided such that the number of layout correcting portions can be more reduced in comparison with the prior art in which the processing is performed based on the uniform restriction value of the parallel line length. As a consequence, it is possible to reduce the number of processing man-hours, and further, to suppress an increase in area. Moreover, needless cell insertion or cell sizing can be prevented by determining not to correct a portion which has been corrected in the prior art, thus producing the effect of suppression of an increase in electric power consumption.

### Third Embodiment

A description will be given below of a crosstalk checking method in a third embodiment according to the present invention.

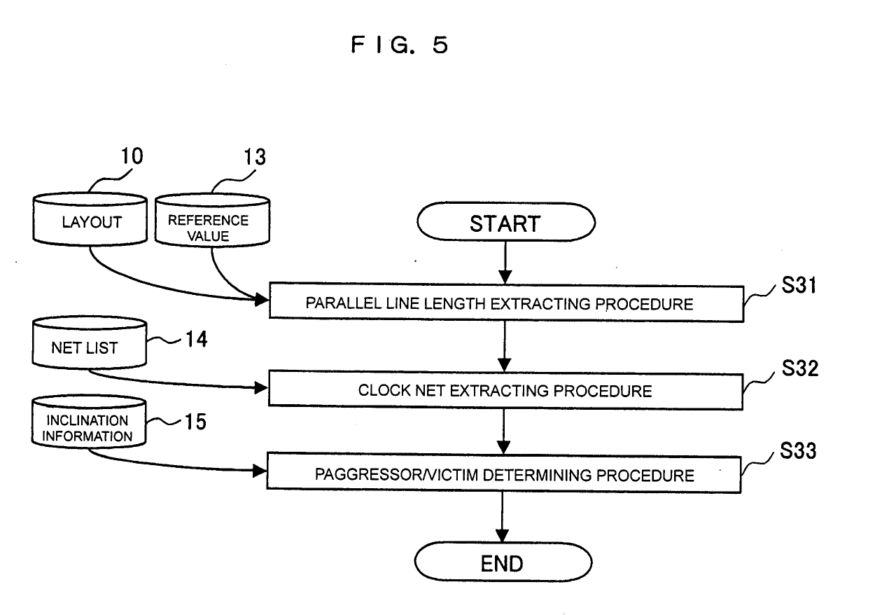

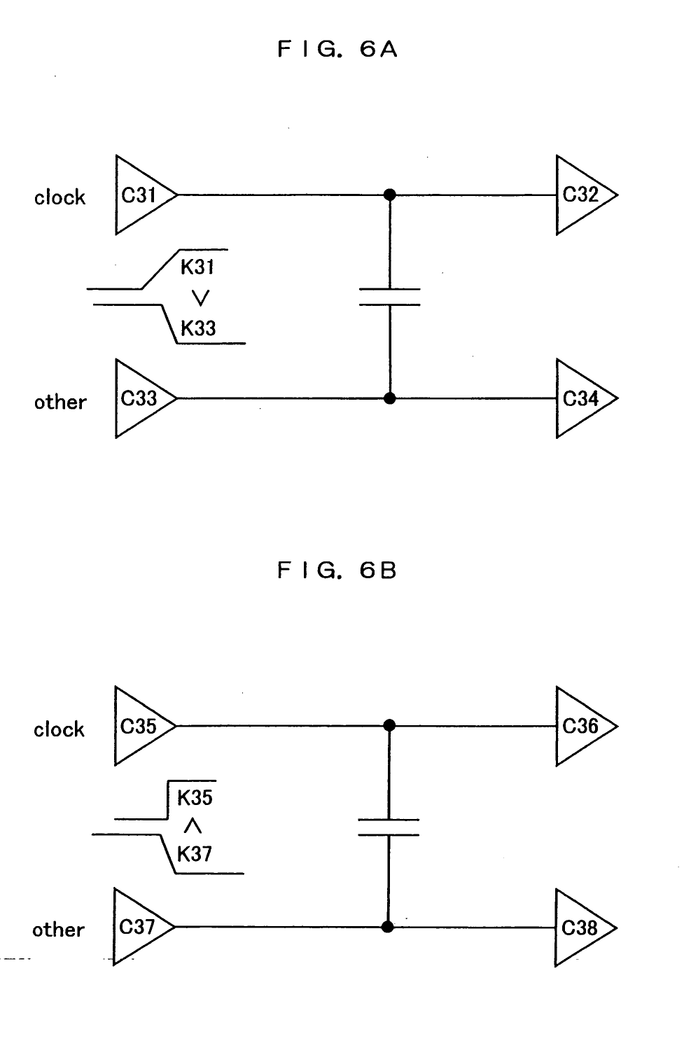

FIG. 5 is a flowchart illustrating the technique for checking a parallel line length while paying attention to a clock line in determining a portion at which crosstalk occurs in a layout; and FIGS. 6A and 6B are diagrams illustrating specific examples of FIG. 5.

In FIG. 5, step S31 designates a parallel line length extracting procedure; step S32 denotes a clock net extracting procedure; step S33, an aggressor/victim determining procedure; reference numeral 14, a net list; and reference numeral 15, information on inclination of a signal waveform of each of cells. In FIGS. 6A and 6B, reference characters C31 and C32 designate cells on a clock line; C33 and C34, cells on a normal signal line; K31, an inclination of a signal waveform at an output terminal of the cell C31; K33, an inclination of a signal waveform at an output terminal of the cell C33; C35 and C36, cells on another clock line; C37 and C38, cells on another normal signal line; K35, an inclination of a signal waveform at an output terminal of the cell C35; and K37, an inclination of a signal waveform at an output terminal of the cell C37.

In step S31 of the parallel line length extracting procedure, a parallel line length between adjacent lines is extracted based on a layout 10 and a reference value 13. The adjacent lines extracted here are two adjacent lines illustrated in FIGS. 6A and 6B.

Thereafter, in step S32 of the clock net extracting procedure, a path is traced by using the net list 14 and a point of a clock source as inputs, thereby extracting a net constituting a clock. Explanation will be provided below assuming that the line driven by the cell C31 and the line driven by the cell C35 illustrated in FIGS. 6A and 6B are extracted as the clock nets by the above-described clock net extraction.

Subsequently, in step S33 of the aggressor/victim determining procedure, it is determined whether or not the net extracted in step S32 of the clock net extracting procedure is victim based on the inclination of the signal waveform at the output terminal of each of the cells by using information 15 on the inclination of the signal waveform as an input. Here, the inclination of the signal waveform signifies a signal transition time at which a voltage varies from zero to VDD or from VDD to zero. In other words, the inclination of the signal waveform signifies the transition time, but not a gradient. Furthermore, the aggressor indicates a line which gives an influence of crosstalk; in contrast, the victim indicates a line which suffers the influence of the crosstalk so as to generate a delay fluctuation or a glitch.

A detailed description will be given of the determination method. In FIG. 6A, the inclination K31 of the signal waveform at the output terminal of the cell C31 is compared with the inclination K33 of the signal waveform at the output terminal of the cell C33. These inclinations of the signal waveforms are information described in the inclination information 15, and are read in step S33 of the aggressor/victim determining procedure. In the case illustrated in FIG. 6A, the relationship between the inclination K31 of the signal waveform and the inclination K33 of the signal waveform satisfies the following inequality (12) (wherein, the inclination of the signal waveform signifies the transition time, but not a gradient).

K31>K33 (12)

In the case of the relationship expressed by the inequality (12), since the inclination K31 of the signal waveform is greater, it is determined that the clock line driven by the cell C31 is the victim. In contrast, as illustrated in FIG. 6B, if the relationship expressed in an inequality (13) is established, it is determined that the clock line driven by the cell C35 is the aggressor.

K35<K37 (13)

Hereinafter, as to all of the adjacent lines, it is determined that the clock line is the aggressor or the victim by comparing the magnitudes of the inclinations of the signal waveforms.

Finally, it is determined whether or not the clock net already extracted in step S32 of the clock net extracting procedure is the victim. If there is a clock net which is the victim, the clock net is output.

Here, explanation will be provided on the significance of extraction of the clock net which is the victim. When the clock net is delayed and fluctuated by the crosstalk, the incorporation of a skew in the entire LSI is collapsed, thereby possibly inducing an erroneous operation. Moreover, when a glitch occurs, a clock is generated at an unexpected timing, thereby generating a logical error so as to induce an erroneous operation. That is to say, in consideration of the crosstalk, the design by which the clock is the victim needs to be corrected since there arises a problem from the viewpoint of a quality.

In correcting the clock net, since the clock net incorporates the skew, the clock net is not corrected but the adjacent net is corrected.

As described above, it is possible to fabricate an LSI of high reliability, which is not deficient on the market, by verifying whether or not the crosstalk occurs at the clock net while paying attention to the clock net, with an attendant effect of enhancing a yield.

### Fourth Embodiment

A description will be given below of a crosstalk checking method in a fourth embodiment according to the present invention.

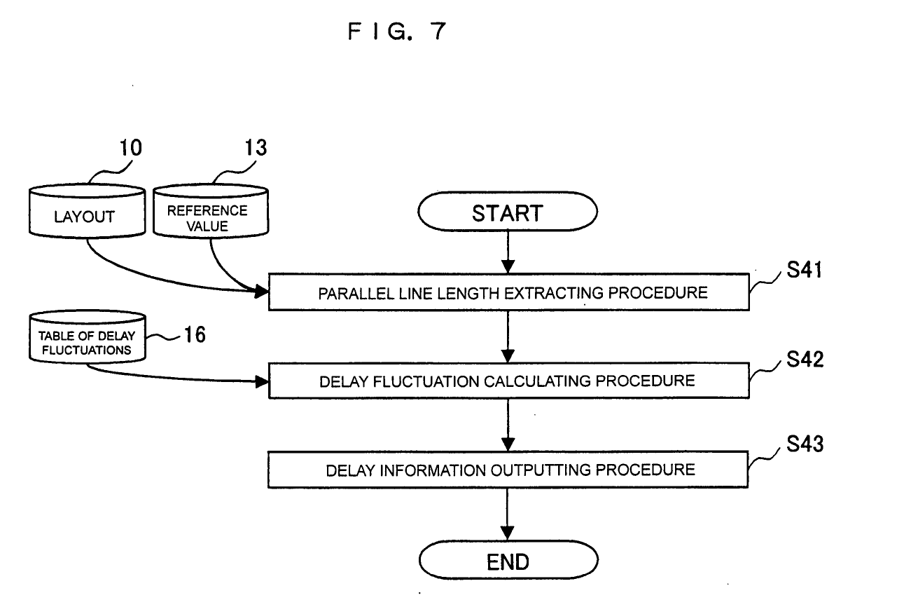

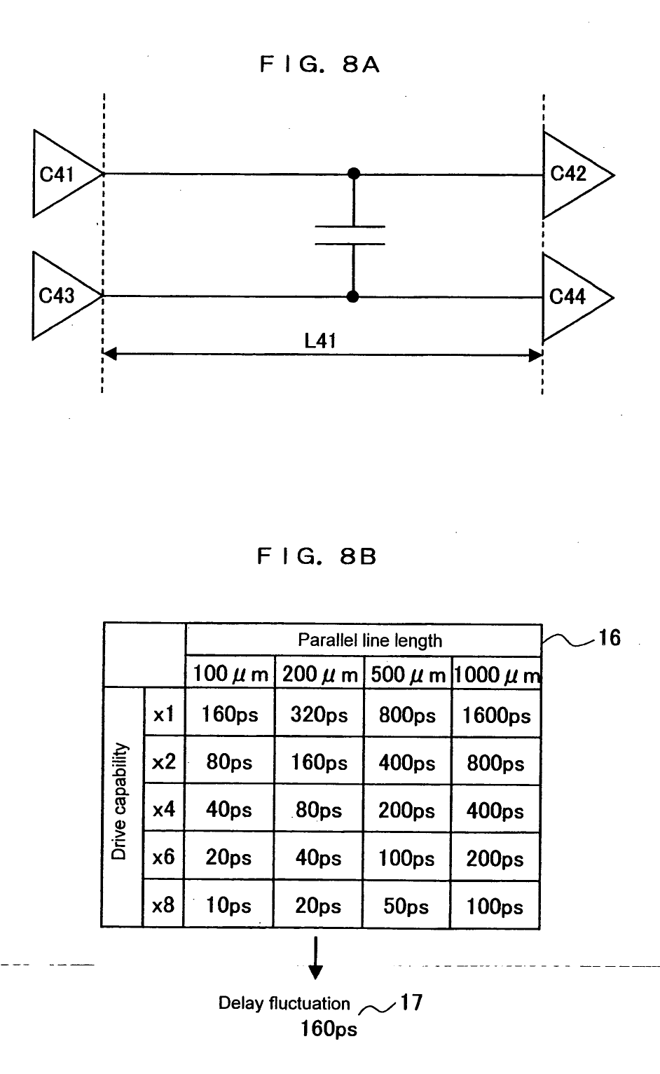

FIG. 7 is a flowchart illustrating a method for calculating a delay fluctuation based on a parallel line length between adjacent lines, so as to verify a timing in determining a portion at which crosstalk occurs in a layout; FIGS. 8A and 8B are a diagram and a table illustrating a specific example of FIG. 7, respectively.

In FIG. 7, step S41 designates a parallel line length extracting procedure; step S42 denotes a delay fluctuation calculating procedure; step S43 designates a delay information outputting procedure; and reference numeral 16 denotes a table of delay fluctuations. In FIGS. 8A and 8B, reference character C41 to C44 designate cells; reference character L41 denotes a parallel line length; reference numeral 16 is the table showing the interrelation among the parallel line lengths, drive capabilities and the delay fluctuations; and reference numeral 17 denotes delay fluctuations calculated based on the table 16.

In step S41 of the parallel line length extracting procedure, a parallel line length between adjacent lines is extracted based on a layout 10 and a reference value 13. The adjacent lines extracted here are adjacent lines illustrated in FIG. 8A. Lines driven by the cells C41 and C43, respectively, are adjacent to each other at the parallel line length L41. The line driven by the cell C41 is determined to be a victim based on inclinations of waveforms of output signals from the cells C41 and C43.

Subsequently, in step S42 of the delay fluctuation calculating procedure, the delay fluctuated by crosstalk is calculated based on the parallel line length L41 and the drive capability of the cell c41 in reference to the table 16 of the delay fluctuations. The table 16 of the delay fluctuations is a table showing the relationship between the parallel line length and the drive capability, where values in the table are interpolated in accordance with an arbitrary interpolation algorithm.

Thereafter, in step S43 of the delay information outputting procedure, the result calculated in step S42 of the delay fluctuation calculating procedure is output as the delay fluctuation 17. A standard delay format (abbreviated as “an SDF”) is often used in a method for indicating delay information, and therefore, the delay fluctuation 17 is expressed by an INCREMENTAL description of the SDF. All of the lines which are victims undergo the delay information, thus creating the delay information of a design.

Finally, a portion at which a timing error occurs caused by the crosstalk is specified by verifying a timing based on the delay information and the delay information when no crosstalk occurs. After specifying, a layout is corrected with respect to the portion at which the timing error occurs, so that the timing error caused by the crosstalk can be avoided.

Incidentally, although the table 16 of the delay fluctuations has been exemplified in the table showing the relationship between the parallel line length and the drive capability in the present embodiment, the same processing can be performed if a table consists of various kinds of values by adding information such as a type of cell, a line pitch or a line layer. Furthermore, the table 16 of the delay fluctuations has been previously prepared by using a circuit simulator such as “hspice” under various conditions.

As described above, the delay fluctuation fluctuated by the crosstalk is calculated based on the parallel line length or the like, and then, the timing is verified, so that the portion at which the crosstalk occurs can be found. By this technique, the design need not be corrected at the portion having a sufficient timing even if the parallel line length between the adjacent lines is great, thus reducing the correcting man-hours.

### Fifth Embodiment

A description will be given below of a crosstalk checking method in a fifth embodiment according to the present invention.

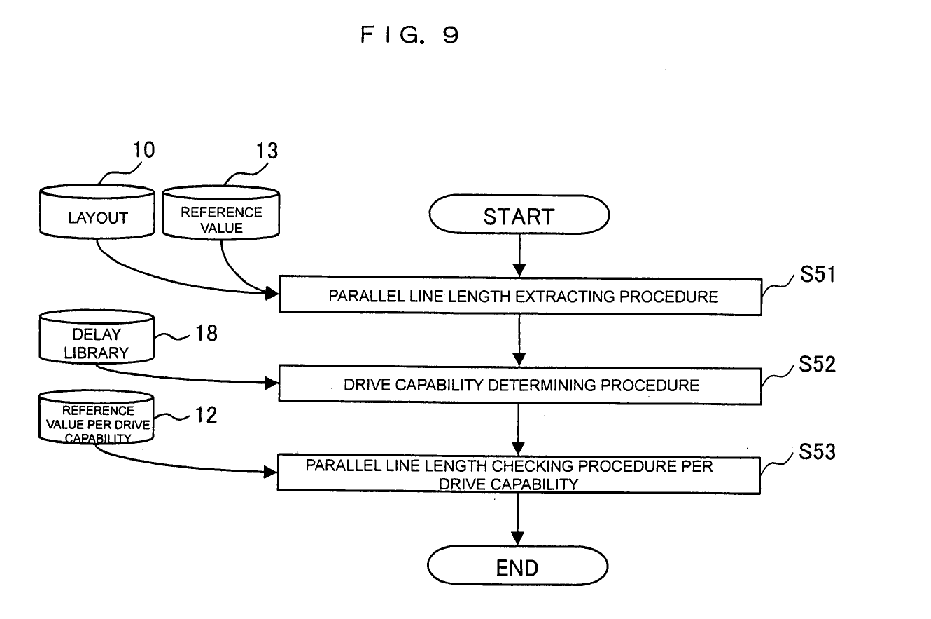

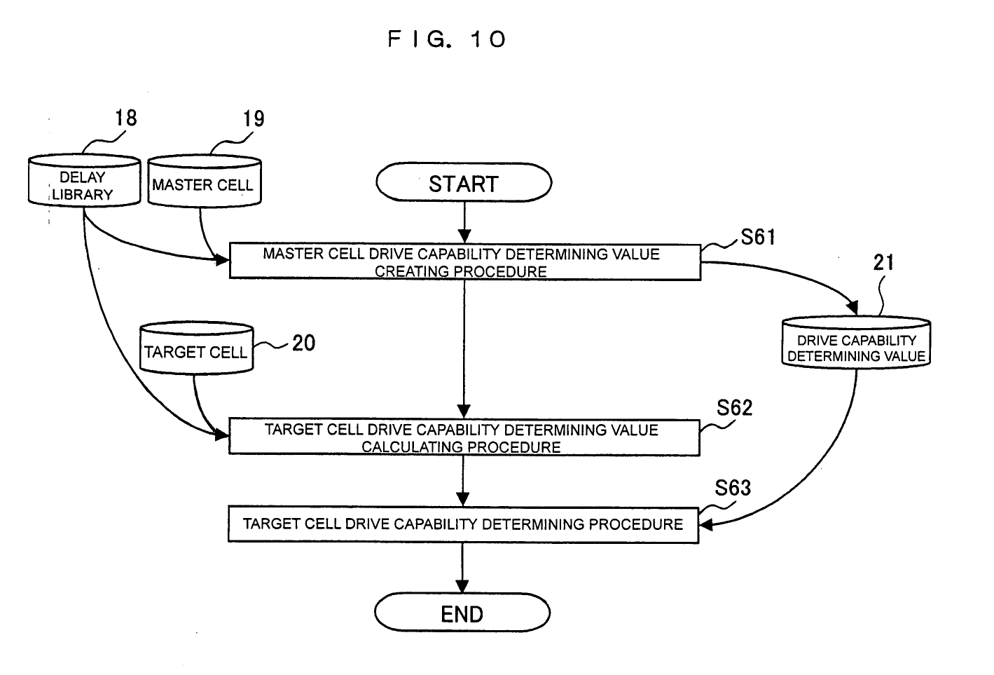

FIG. 9 is a flowchart illustrating a method for determining drive capability with respect to a block/cell having an unknown drive capability such as an intellectual property (abbreviated as “an IP”), so as to restrict a parallel line length in determining a portion at which crosstalk occurs in a layout; and FIG. 10 is a flowchart illustrating a detailed subdividing procedure of the drive capability determining procedure illustrated in FIG. 9.

In FIG. 9, step S51 designates a parallel line length extracting procedure; step S52 denotes a drive capability determining procedure; and reference numeral 18 designates a delay library. In FIG. 10, step S61 designates a master cell drive capability determining value creating procedure; step S62 denotes a target cell drive capability determining value calculating procedure; step S63 designates a target cell drive capability determining procedure; reference numeral 19 denotes a master cell; and reference numeral 20 designates a target cell.

First of all, explanation will be provided on the drive capability. The drive capability is a model of a transistor structure at a stage of a cell output, wherein a maximum value of a drivable capacity is varied according to the size of a transistor. Therefore, it is general to fabricate several kinds of cells having the same function and being different only in drive capability. Since it is not found as to where the cell is used during a design, a cell having a weak drive capability is used at a portion at which a capacity to be driven is small; in contrast, a cell having a strong drive capability is used at a portion at which a capacity to be driven is large. Here, the stronger the drive capability, the greater the size of the transistor, thereby increasing the area of the cell.

For example, in the case of a cell having an inverter function, first, an inverter cell having a basic drive capability is developed. And then, several kinds of cells having the same function and being different only in drive capability such as an inverter cell having a double drive capability or an inverter cell having a triple drive capability with respect to the inverter cell having the basic drive capability are prepared. Here, the basic drive capability is determined or the cell having a multiple of drive capability is prepared according to processes in many cases. If a using process is varied, a creation idea also is varied. Therefore, in the case where the IP block or the cell is introduced from the outside of a company, it is usual that the concept of the drive capability is different from that of its own company, and further, the drive capability of the introduced IP block or cell is unclear in many cases.

However, since the crosstalk markedly depends on the drive capability of the cell which drives the adjacent lines, means for determining the drive capability is required also with respect to the block or cell having an unknown drive capability. Thus, a description will be given below of the drive capability determining method with respect to the block or cell having an unknown drive capability, which is a feature of the present invention.

In step S51 of the parallel line length extracting procedure, the parallel line length between the adjacent lines is extracted based on a layout 10 and a reference value 13.

Next, in step S52 of the drive capability determining procedure, the drive capability is calculated based on the delay library 18 describing the cell delay information. In this manner, the drive capability is determined with respect to all of the blocks or cells. In step S52 of the drive capability determining procedure, there arises no problem with respect to the cell developed in the company since the drive capability is defined. However, it is important to determine the drive capability with respect to the IP block introduced from the outside of the company. Thus, the drive capability determining procedure in step S52 will be described in more detail in reference to FIG. 10.

The drive capability determining procedure in step S52 includes the master cell drive capability determining value creating procedure in step S61, the target cell drive capability determining value calculating procedure in step S62 and the target cell drive capability determining procedure in step S63. In step S61 of the master cell drive capability determining value creating procedure, a master cell drive capability determining value 21 is calculated by using the delay library 18 describing the delay information on all of the blocks or cells and the master cell 19 as inputs. Here, the master cell signifies a cell which is referred to when the drive capability of the block or cell having the unknown drive capability is determined, wherein it is desirable that a simple inverter or buffer should be set.

The drive capability determining value 21 signifies a value representing the drive capability, which is calculated by using the following equation (14):

Drive capability determining value=(maximum value of inclination of output signal waveform−minimum value of inclination of output signal waveform)/(maximum value of drive capacity−minimum value of drive capacity) (14)

In a general delay library, an inclination of an output signal waveform of a cell is expressed by a function or a table of an inclination of an input signal waveform of a cell and a driving capacity, which is expressed by the drive capacity in the equation (14) in many cases. A numerator in the equation (14) is almost constant irrespective of the strength of the drive capability. Since the drivable capacity becomes greater as the drive capability becomes stronger, a denominator becomes greater. Therefore, the drive capability determining value 21 becomes smaller as the drive capability becomes stronger.

The values expressed by the equation (14) are calculated per drive capability of the master cell. As a result, the drive capability determining value 21 is calculated as a different value per drive capability. As the drive capability becomes stronger, the drive capability determining value 21 is set to be smaller.

Next, in step S62 of the target cell drive capability determining value calculating procedure, the drive capability determining value is calculated in the same manner in accordance with the equation (14) by using the target cell 20 having the unknown drive capability and the delay library 18 as inputs.

Subsequently, in step S63 of the target cell drive capability determining procedure, it is determined as to what the drive capability of the target cell 20 corresponds to based on the drive capability determining value 21 and the drive capability determining value of the target cell 20.

Finally, in step S53 of a parallel line length checking procedure per drive capability, the parallel line length between the adjacent lines is checked in accordance with a reference value 12 per drive capability since the drive capability is determined with respect to all of the blocks and the cells. The details of the parallel line length checking procedure per drive capability in step S53 have been described in the second embodiment. In this check, a layout is corrected at a portion to be determined as a portion at which crosstalk occurs.

As described above, although there is no case where the drive capability is unknown in the design in the company, the drive capability determining method according to the present invention is applied if the drive capability is unknown in the case where the IP or cell prepared outside of the company is used, thereby determining the drive capability, so as to check the portion at which the crosstalk occurs. Consequently, only the portion which must be really corrected can be corrected, thus preventing a needless increase in area.

Incidentally, although the drive capability determining value has been calculated based on only the drive capacity in the equation (14), the inclination of the input signal waveform also may be used as an element of the equation.

### Sixth Embodiment

A description will be given below of crosstalk checking method in a sixth embodiment according to the present invention.

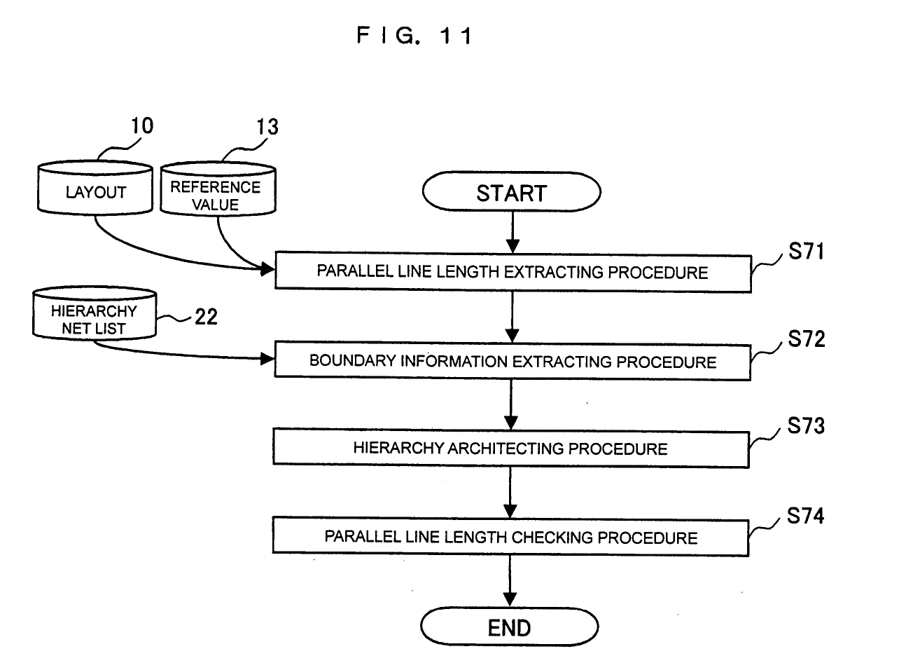

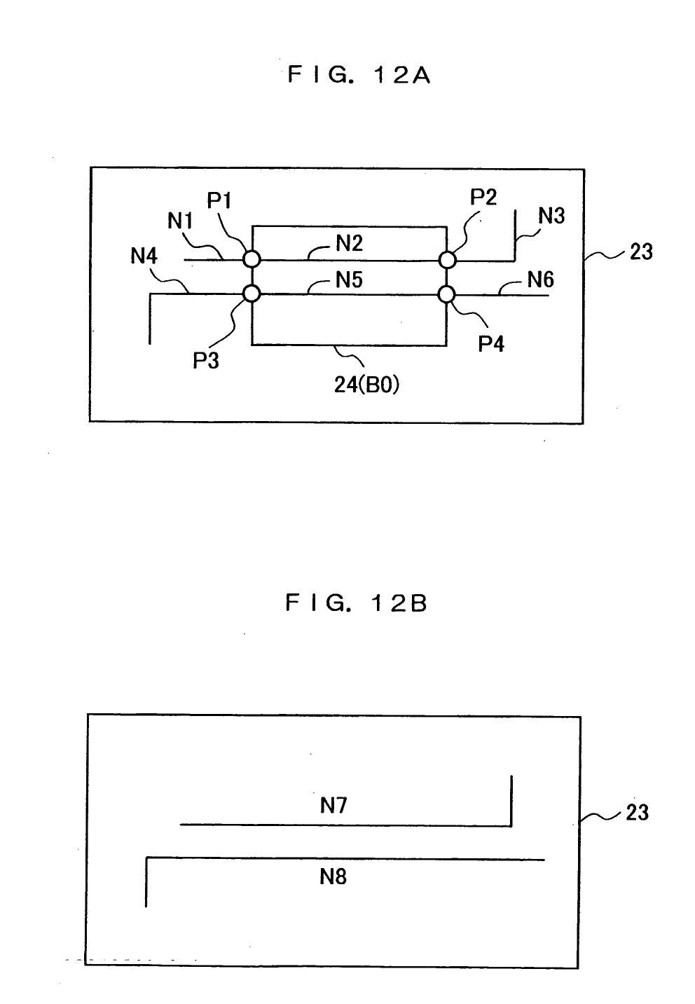

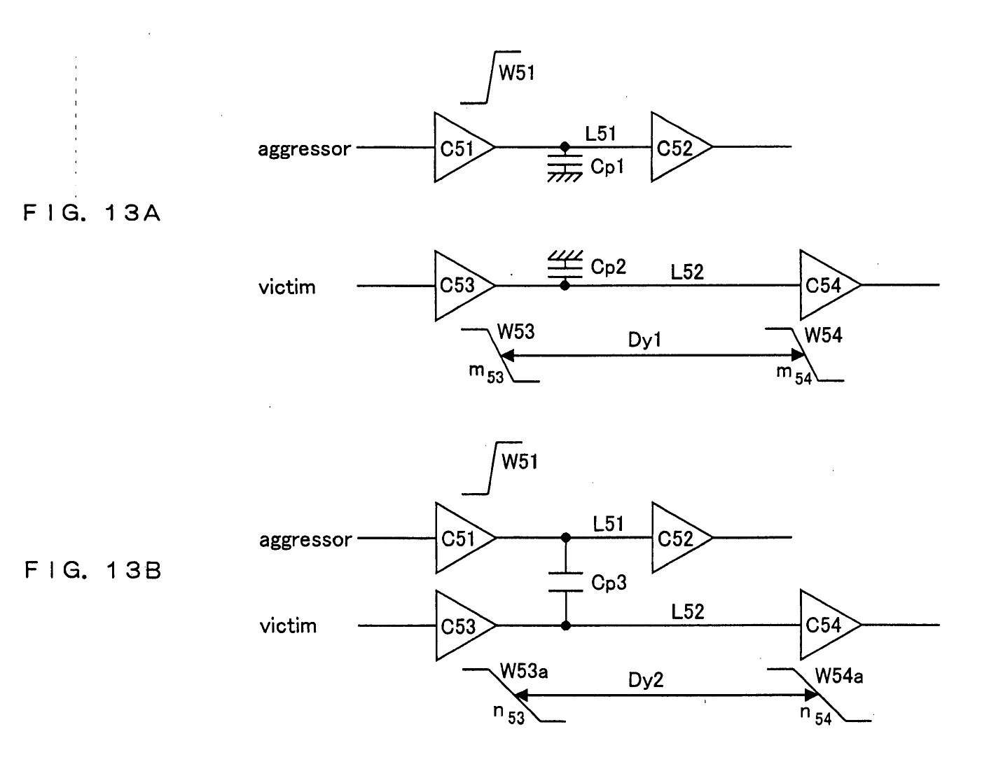

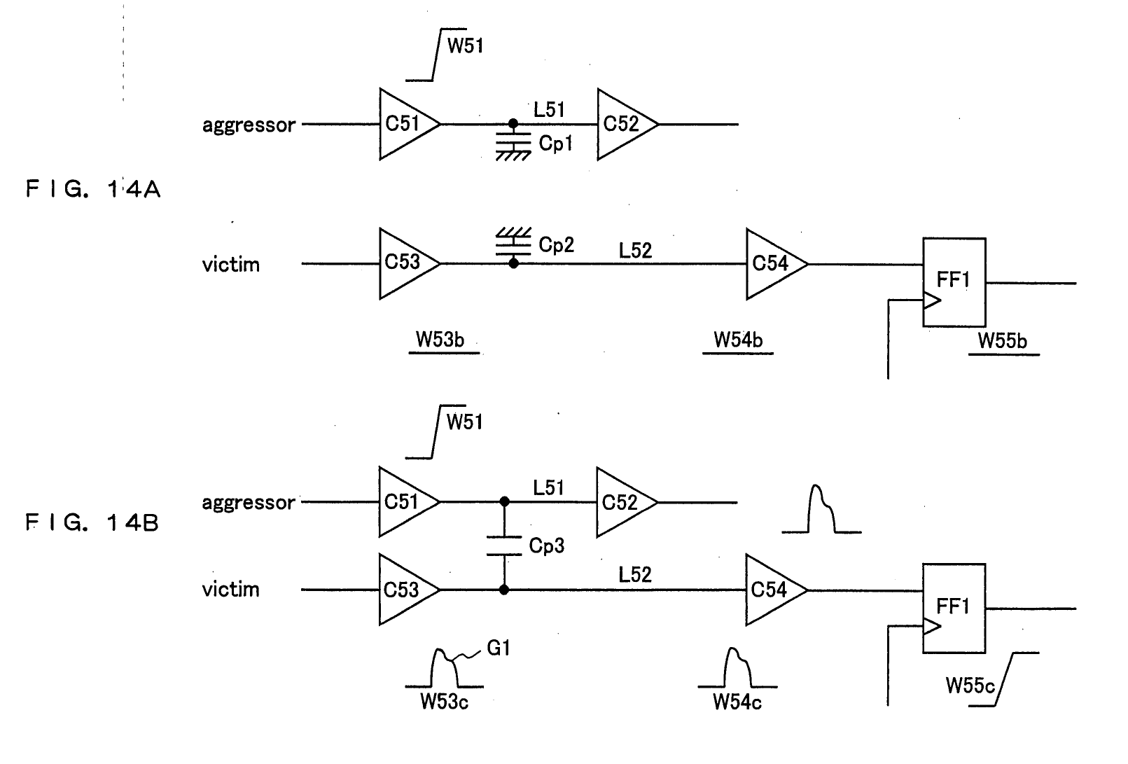

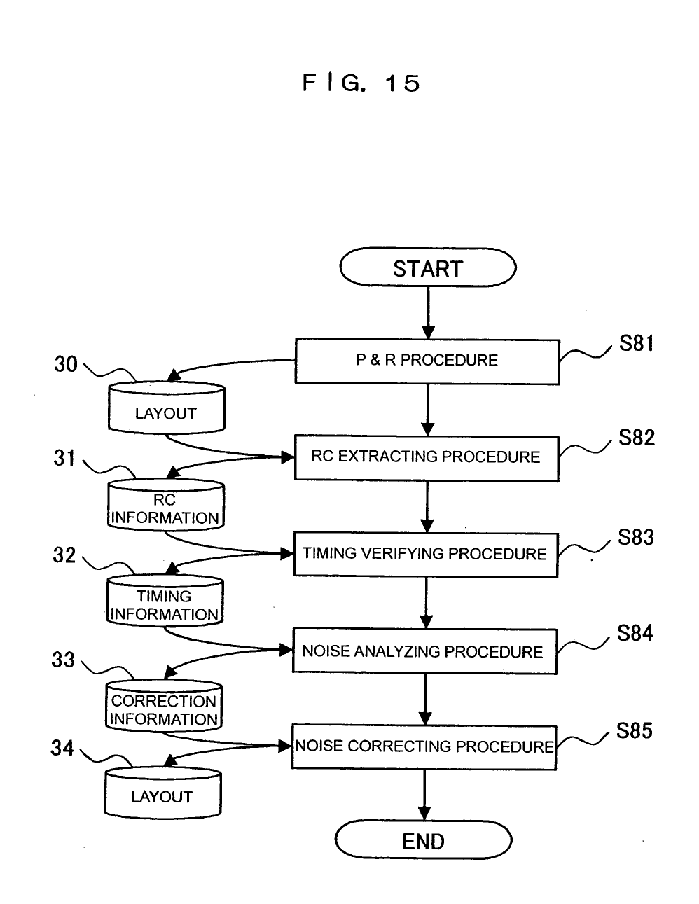

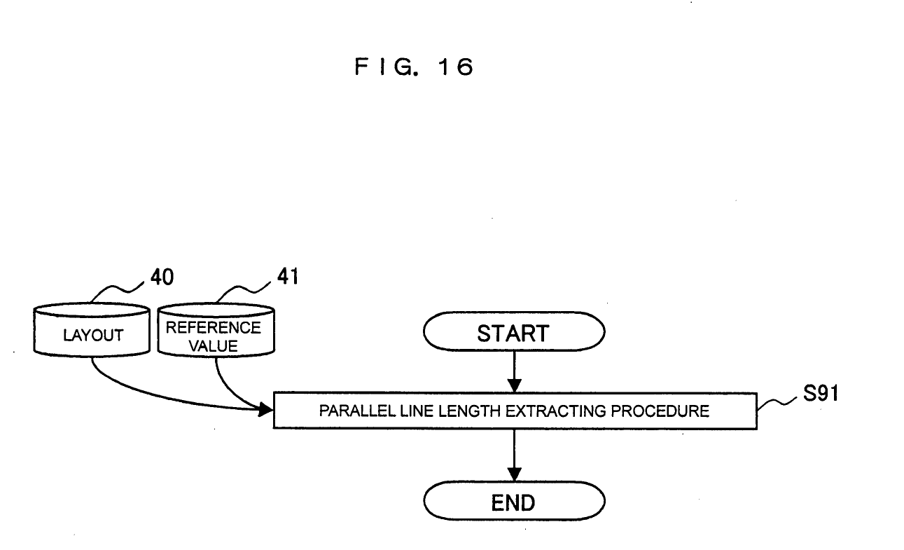

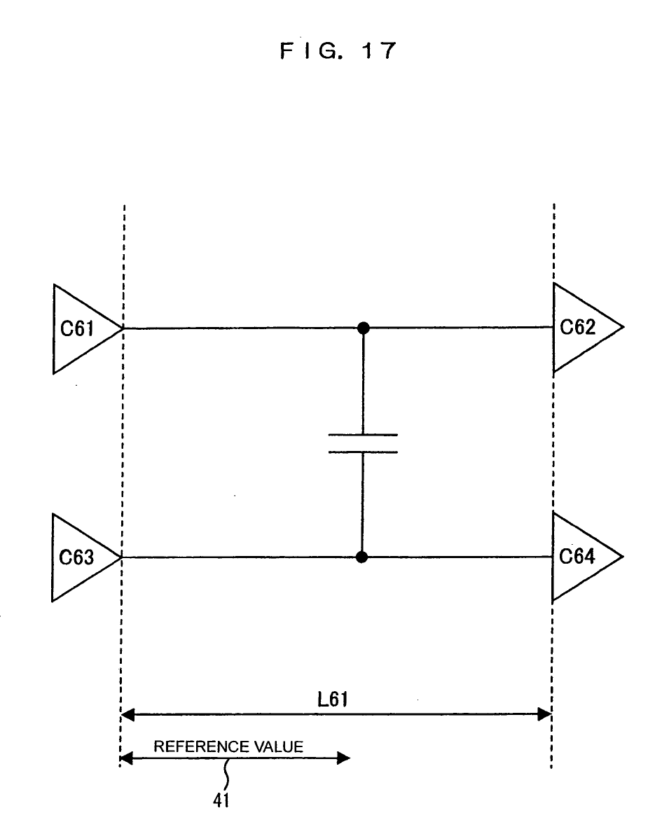

FIG. 11 is a flowchart illustrating a method for checking a parallel line length between adjacent lines adjacent to each other across a hierarchy with respect to a hierarchy design in determining a portion at which crosstalk occurs in a layout; and FIGS. 12A and 12B are diagrams illustrating specific examples of the parallel line length checking method illustrated in FIG. 11.

In FIG. 11, step S71 designates a parallel line length extracting procedure; step S72 denotes a boundary information extracting procedure; step S73 designates a hierarchy architecting procedure; step S74 denotes a parallel line length checking procedure; and reference numeral 22 designates a hierarchy net list including all of hierarchies. In FIG. 12, reference numeral 23 denotes a TOP hierarchy of a design; reference numeral 24 designates a block under the TOP hierarchy 23; reference characters P1 to P4 denote terminals of the block 24; and reference characters N1 to N6 designate nets.

In step S71 of the parallel line length extracting procedure, the parallel line length between the adjacent lines is extracted based on a layout 10 and a reference value 13. The parallel line length between the adjacent lines is extracted with respect to all of hierarchies. However, at this time, only the parallel line length in the same hierarchy is checked.

Subsequently, in step S72 of the boundary information extracting procedure, connection information between the TOP hierarchy and the block is extracted by using the hierarchy net list 22 describing all of blocks in the hierarchy as an input.

The details will be explained in reference to FIGS. 12A and 12B. The block 24 exists in the TOP hierarchy 23. The nets N1, N3, N4 and N6 in the TOP hierarchy 23 are connected to the nets N2 and N5 inside of the block 24 via terminals P1, P1, P3 and P4 of the block 24, respectively.

In step S72 of the boundary information extracting procedure, the interrelation among the block name, the terminal name of the block, the net name in the TOP hierarchy connected to the terminal and the net name inside of the block is established as a format 1 shown in Table 1.

TABLE 1
Format 1

| | | net name in | net name |
|---|---|---|---|
| block name | terminal name | TOP hierarchy | inside of block |
| BO | P1 | N1 | N2 |
| BO | P2 | N3 | N2 |
| BO | P3 | N4 | N5 |
| BO | P4 | N6 | N5 |

Thereafter, in step S73 of the hierarchy architecting procedure, the parallel line lengths in the hierarchies of the adjacent lines across the hierarchy are summed up. In step S71 of the parallel line length extracting procedure, the parallel line length is assumed to be extracted as shown in Table 2.

TABLE 2
Extraction result

| Net name 1 on | Net name 2 on | parallel line |
|---|---|---|
| adjacent lines | adjacent lines | length |
| N2 | N5 | 100 μm |
| N1 | N4 | 200 μm |
| N3 | N6 | 300 μm |

First of all, the nets are connected in accordance with the format 1. Since the nets N1 and N3 in the TOP hierarchy are connected to the net N2 of the block 24 via the terminals P1 and P1, the nets N1, N2 and N3 are identified as one net N7. In the same manner, since the nets N4 and N6 in the TOP hierarchy are connected to the net N5 of the block 24 via the terminals P3 and P4, the nets N4, N5 and N6 are identified as one net N8. The extraction result shown in Table 2 is corrected in accordance with the net connection identification. The corrected extraction result is shown in Table 3.

TABLE 3
corrected Extraction result

| Net name 1 on | Net name 2 on | parallel line |
|---|---|---|
| adjacent lines | adjacent lines | length |
| N7 | N8 | 100 μm |
| N7 | N8 | 200 μm |
| N7 | N8 | 300 μm |

Thus, the nets N7 and N8 are identified to be parallel to each other within the range of 600 μm resulting from the summation of 100 μm, 200 μm and 300 μm based on the corrected extraction result.

Next, in step S74 of the parallel line length checking procedure, a portion at which crosstalk occurs to be corrected is extracted by applying the prior art and the methods described in the first to third embodiments.

As described above, the adverse influence of the crosstalk can be alleviated by developing the hierarchy and checking the parallel line length even in the hierarchy design.

Although the description has been given of the case where only one block 24 exists in the TOP hierarchy 23, the same method is repeated even if there are other blocks, thereby performing the processing. Furthermore, if the block 24 includes therein a sub block, the processing is performed while regarding the block 24 as the TOP hierarchy, and then, the above-described method is applied, thus performing the processing. Moreover, although the net name after the hierarchy development has been designated by the name different from the original name, such as the net N7 or N8, it is preferable that the net name after the hierarchy development should be designated by the net name Ni or N4 in the TOP hierarchy 23. This is because inconsistency in the net list occurs to make the following layout correction difficult when the net name after the hierarchy development is designated by the different name.

As described above, according to the present invention, it is possible to correct only the portion actually required to be corrected at which the delay time is fluctuated or the glitch occurs due to the crosstalk, thereby reducing the processing man-hours and suppressing an increase in area or electric power consumption in comparison with in the prior art. Additionally, only the portion at which the crosstalk is actually liable to occur is corrected, thus reducing a deficient product generating rate.

From the above description, it will be apparent what the present invention provides.

What is claimed is:

1. A crosstalk checking method comprising the steps of:
extracting a parallel line length between adjacent lines by inputting a layout, and further, inputting a reference value per pitch describing restriction values of parallel line lengths different according to a line pitch; and
calculating the line pitch with respect to the adjacent lines extracted in the parallel line length extracting step, comparing the parallel line length between the adjacent lines with the reference value per pitch, and thus, determining a portion at which crosstalk occurs in the case where the parallel line length is greater.

2. A crosstalk checking method comprising the steps of:
extracting a parallel line length between adjacent lines by inputting a layout, and further, inputting a reference value per drive capability describing restriction values of parallel line lengths different according to drive capability of a cell for driving a line; and
extracting the reference value per drive capability corresponding to the drive capability of the cell for driving the line with respect to the adjacent lines extracted in the parallel line length extracting step, comparing the parallel line length between the adjacent lines with the reference value, and thus, determining a portion at which crosstalk occurs in the case where the parallel line length is greater.

3. A crosstalk checking method comprising the steps of:
extracting a parallel line length between adjacent lines by inputting a layout, and further, inputting a reference value describing a restriction value of the parallel line length;
tracing a path by using a net list and a point of a clock source as inputs, so as to extract a clock net; and
classifying the adjacent lines into a line of a victim which suffers an influence of the crosstalk and a line of an aggressor which gives the influence of the crosstalk based on the magnitude of an inclination of a signal waveform at a cell output terminal with respect to the extracted net by using inclination information describing the inclination of the signal waveform at the cell output terminal described in the net list, as inputs, so as to determine whether or not the net is to suffer the influence of the crosstalk.

4. A crosstalk checking method comprising the steps of:
extracting a parallel line length between adjacent lines by inputting a layout, and further, inputting a reference value describing a restriction value of the parallel line length;
inputting the parallel line length, and further, inputting a delay fluctuation table describing delay fluctuation fluctuated in the case of the occurrence of the crosstalk according to driving capabilities of cells for driving the parallel lines, so as to calculate how much delay fluctuation the parallel line length extracted in the parallel line length extracting procedure corresponds to; and
outputting the delay fluctuation calculated in the delay fluctuation calculating step as delay information for verifying a timing.

5. A crosstalk checking method comprising the steps of:
extracting a parallel line length between adjacent lines by inputting a layout, and further, inputting a reference value describing a restriction value of the parallel line length;
inputting a library, in which delay information is described, and further, inputting a standard master cell having a plurality of drive capabilities, calculating a determining value of the drive capability per drive capability of the master cell based on waveform inclination information of an output signal in the library with respect to a target cell block whose drive capability is unknown, and subsequently, calculating a determining value of the drive capability of the target cell block, so as to determine the drive capability of the target cell block by comparison; and
determining the crosstalk based on the restriction value of the parallel line length corresponding to the drive capability determined in the drive capability determining step with respect to the adjacent lines extracted in the parallel line length extracting step in the case where the adjacent lines are driven by the target cell block.

6. A crosstalk checking method comprising the steps of:
extracting a parallel line length between adjacent lines per hierarchy with respect to a hierarchically designed layout by inputting a layout, and further, inputting a reference value describing a restriction value of a parallel line length;
checking a connection relationship between lines across a hierarchy in a net list of each of hierarchies so as to extract boundary information;
calculating the parallel line length across the hierarchy by summing the parallel line lengths extracted per hierarchy with respect to the same net of the adjacent lines across the hierarchy; and
determining a portion at which crosstalk occurs in comparison of the parallel line length across the hierarchy with a predetermined reference value.
